(19) United States
(12) Patent Application Publication
(10) Pub. No.: US 2026/0198332 A1
(43) Pub. Date: Jul. 9, 2026

(54) METHOD OF MANUFACTURING SEMICONDUCTOR PACKAGE

(71) Applicant: Samsung Electronics Co., Ltd., Suwon-si (KR)

(72) Inventors: Eungchul KIM, Suwon-si (KR); Unbyoung KANG, Suwon-si (KR); Byeongchan KIM, Suwon-si (KR); Dongjoon OH, Suwon-si (KR)

(73) Assignee: Samsung Electronics Co., Ltd., Suwon-si (KR)

(21) Appl. No.: 19/430,625

(22) Filed: Dec. 23, 2025

(30) Foreign Application Priority Data
Jan. 9, 2025 (KR) 10-2025-0003740

(51) Int. Cl. H10W 70/05; H10P 52/40; H10W 74/01

(52) U.S. Cl. CPC H10W 70/093; H10P 52/403; H10W 74/01

(57) ABSTRACT

Provided is a method of manufacturing a semiconductor package. The method includes forming a wiring structure, applying a photoresist layer onto the wiring structure, exposing and developing the photoresist layer to form a photoresist pattern including a plurality of openings, forming at least one bump pad by filling at least a portion of at one of the plurality of openings with a conductive material, and planarizing the at least one bump pad by selectively polishing the at least one bump pad through a chemical mechanical processing (CMP) process using a slurry and a polishing pad.

### CROSS-REFERENCE TO RELATED APPLICATION

This application is based on and claims priority under 35 U.S.C. § 119 to Korean Patent Application No. 10-2025-0003740, filed on Jan. 9, 2025, in the Korean Intellectual Property Office, the disclosure of which is incorporated by reference herein in its entirety.

### BACKGROUND

The inventive concepts relate to a method of manufacturing a semiconductor package, and more particularly, to a method of manufacturing a semiconductor package, including planarizing a copper pad using selectively polishing.

In the process of manufacturing semiconductor devices and semiconductor packages, high-density wiring may be formed by selectively removing a copper plating layer by using a subtractive process (SAP). However, as the number of stacks increases, forming fine pitch copper wiring becomes difficult due to undulation. In particular, when bump pads formed on a top layer of a redistribution layer are not formed accurately, shorts, voids, and/or joint defects may occur during a soldering process.

Accordingly, research is being conducted on planarizing technology to improve soldering joint defects caused by the accumulated undulation and fine pitch of copper wiring. The chemical mechanical polishing (CMP) process is mainly used for polishing and planarizing surfaces of metal layers. As the integration of semiconductor devices and semiconductor packages increases, the development of technology to improve the reliability of the polishing process for fine pattern manufacturing is becoming important.

### SUMMARY

The inventive concepts provide a method of manufacturing a semiconductor package by adjusting a polishing selectivity between a polymer and copper to planarize a copper pad and reduce a height deviation of the copper pad.

The inventive concepts also provide a method of removing undulation of a bump pad and a redistribution layer in the process of manufacturing semiconductor devices.

The inventive concepts are not limited to the mentioned above, and other inventive concepts may be clearly understood by those skilled in the art.

According to an aspect of the inventive concepts, there is provided a method of manufacturing a semiconductor package, the method including forming a wiring structure, applying a photoresist layer onto the wiring structure, exposing and developing the photoresist layer to form a photoresist pattern including a plurality of openings, forming at least one bump pad by filling at least a portion of at one of the plurality of openings with a conductive material, and planarizing the at least one bump pad by selectively polishing the at least one bump pad through a chemical mechanical processing (CMP) process using a slurry and a polishing pad.

According to an aspect of the inventive concepts, there is provided a method of manufacturing a semiconductor package, the method including forming an insulating film, applying a photoresist layer onto the insulating film, exposing and developing the photoresist layer to form a photoresist pattern including a plurality of openings, forming a metal material film in the plurality of openings, selectively polishing and planarizing the metal material film through a chemical mechanical processing (CMP) process, the CMP process using a slurry and a polishing pad, and removing the photoresist pattern.

According to an aspect of the inventive concepts, there is provided a method of manufacturing a semiconductor package, the method including forming a wiring structure, applying a photoresist layer onto the wiring structure, exposing and developing the photoresist layer to form a photoresist pattern including a plurality of openings, forming at least one bump pad by filling at least a portion of at least one of the plurality of openings with a conductive material, planarizing the at least one bump pad by selectively polishing the at least one bump pad through a chemical mechanical processing (CMP) process, the CMP process using a slurry and a polishing pad, forming, within a remainder of the at least one of the plurality of openings, a metal pad on the planarized at least one bump pad, removing the photoresist pattern, disposing a semiconductor chip on the metal pad, and forming a molding layer surrounding the semiconductor chip.

According to an aspect of the inventive concepts, there is provided a chemical mechanical polishing (CMP device) including a platen configured to rotate around an axis, a polishing pad on the platen; a carrier head configured to provide a wafer to the polishing head; and a slurry supply nozzle configured to dispense a slurry from a slurry source to the polishing pad.

The polishing pad may have a porous structure configured to selectively polish a bump pad in the wafer, with respect to the photoresist pattern.

The slurry may comprise 1 percent by weight (wt %) or less of abrasive particles.

The slurry may comprise 5 percent by weight (wt %) or less of an oxidizing agent, the oxidizing agent configured to a metal ion by oxidizing the conductive material.

### BRIEF DESCRIPTION OF THE DRAWINGS

Embodiments will be more clearly understood from the following detailed description taken in conjunction with the accompanying drawings in which:

FIG. 1 is a partially cut-away perspective view schematically illustrating some components of a chemical mechanical polishing (CMP) device, according to at least one example embodiment;

FIG. 2 is a schematic plan view of a polishing pad of a CMP device, according to at least one example embodiment;

FIG. 3 is a schematic plan view of a polishing pad of a CMP device, according to at least one example embodiment;

FIG. 4 is a schematic plan view of a polishing pad of a CMP device, according to at least one example embodiment;

FIG. 5A is a schematic cross-sectional view of the polishing pad of FIG. 4 taken along line A-A′;

FIG. 5B is a schematic cross-sectional view of the polishing pad of FIG. 4 taken along line A-A′′;

FIG. 6 is a schematic cross-sectional view of a polishing pad conditioner of a CMP device, according to at least one example embodiment;

FIG. 7 is a schematic cross-sectional view of a semiconductor package according to at least one example embodiment;

FIG. 8 is an enlarged cross-sectional view schematically illustrating portion EX1 in FIG. 7;

FIG. 9 is a flowchart of a method of manufacturing a semiconductor package, according to at least one example embodiment;

FIGS. 10 to 16 are diagrams schematically illustrating a method of manufacturing a semiconductor package, according to at least one example embodiment;

FIG. 17 is a flowchart of a method of manufacturing a semiconductor package, according to at least one example embodiment; and

FIGS. 18 to 23 are diagrams schematically illustrating a method of manufacturing a semiconductor package.

### DETAILED DESCRIPTION OF THE EMBODIMENTS

Hereinafter, embodiments are described in detail with reference to the accompanying drawings. The same reference numerals are used for the same components on the drawings, and redundant description thereof is omitted. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

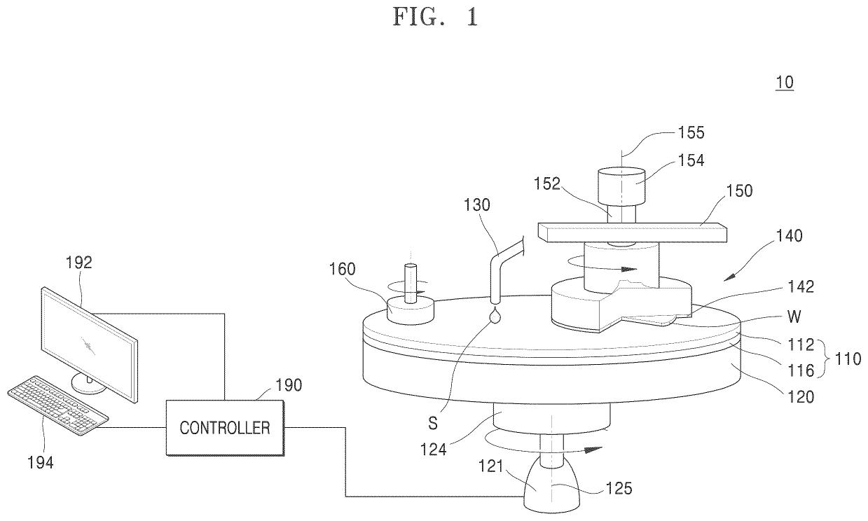

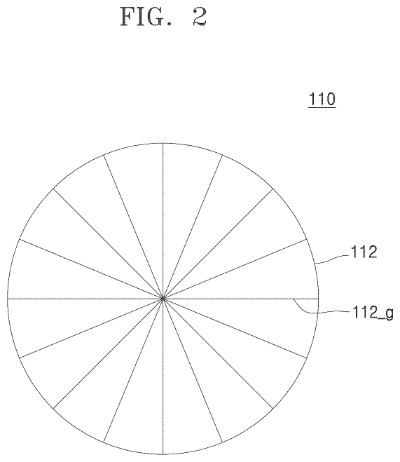

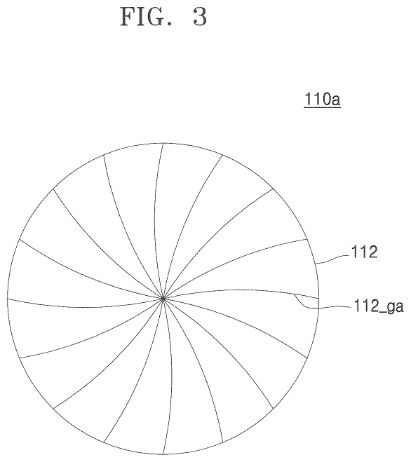

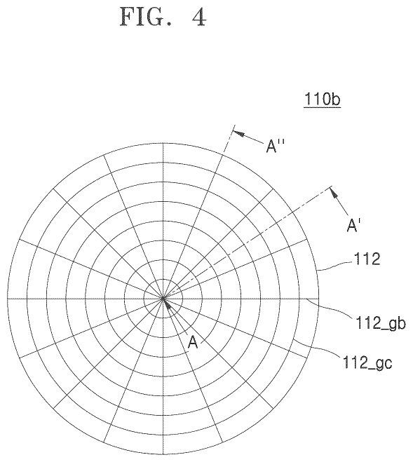

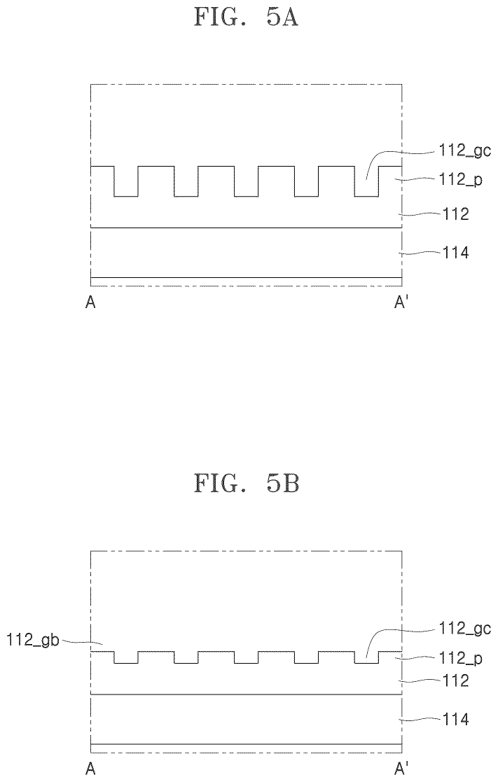

FIG. 1 is a partially cut-away perspective view schematically illustrating some components of a chemical mechanical polishing (CMP) device 10, according to at least one example embodiment. FIG. 2 is a schematic plan view of a polishing pad 110 of the CMP device 10, according to at least one example embodiment. FIG. 3 is a schematic plan view of a polishing pad 110a of the CMP device 10, according to at least one example embodiment. FIG. 4 is a schematic plan view of a polishing pad 110b of the CMP device 10, according to at least one example embodiment. FIG. 5A is a schematic cross-sectional view of the polishing pad 110b of FIG. 4 taken along line A-A′. FIG. 5B is a schematic cross-sectional view of the polishing pad 110b of FIG. 4 taken along line A-A″. FIG. 6 is a schematic cross-sectional view of a polishing pad conditioner 160 of the CMP device 10, according to at least one example embodiment.

Referring to FIG. 1, the CMP device 10 may be used to polish a surface of a wafer W by performing a CMP process. FIG. 1 shows an example of the CMP device 10, which is implemented as a rotary CMP device.

The CMP device 10 may include a polishing pad 110, a platen 120, a slurry port 130, a carrier head 140, a polishing pad conditioner 160, and a controller 190.

The platen 120 of the CMP device 10 may have a rotary disk shape. The platen 120 may be rotatably arranged about a central axis 125 of the platen 120 by using a motor 121 and/or the like. For example, the motor 121 may rotate a drive shaft 124 to rotate the platen 120. The polishing pad 110 may be disposed on a top surface of the platen 120.

According to some example embodiments, the platen 120 may be configured to be a temperature regulated platen. For example, accord to some example embodiments, the platen 120 include one or more fluid channels (not illustrated) configured to allow a temperature-regulating fluid to flow therein. At least some of the fluid channels may extend in a region proximate to the top surface of the platen 120. For example, at least some of the fluid channels, in the region proximate to the top surface of the platen 120, may extend in a direction parallel to the top surface of the platen 120. The fluid channels may be configured to receive the temperature-regulating fluid (e.g., a cooling fluid or a heating fluid) from a fluid supply device. As the temperature-regulating fluid flows into the fluid channels of the platen 120, the temperature of the platen 120 and the temperature of the polishing pad 110 disposed on the platen 120 may be adjusted. The temperature of the platen 120 may be controlled using the temperature-regulating fluid to provide suitable temperature conditions for the polishing process of the wafer W.

The polishing pad 110 may be disposed on the platen 120. The polishing pad 110 may include a polishing pad for CMP. The polishing pad 110 may be provided as a plate having a constant thickness, e.g., a circular plate, but is not limited thereto. When the polishing process is performed, the polishing pad 110 may be in direct contact with a polishing target and may chemically and/or mechanically polish the surface of the polishing target by using nano-abrasive particles in a slurry S to subtract (e.g., remove) material from the polishing target.

The polishing pad 110 may include a polishing layer 112 and a support layer 116. The support layer 116 may support the polishing pad 110 to be attached to the platen 120. The polishing layer 112 may include a polishing surface having a certain roughness. While the CMP process is performed, the polishing surface of the polishing layer 112 may rub against the polishing target to polish the polishing target. The polishing target may include, for example, the wafer W. In some embodiments, the polishing pad 110 may have a roughness for selectively polishing copper among a polymer and copper on the surface of the wafer W which is the polishing target.

The polishing pad 110 may have a porous structure having a plurality of micropores. The micropores of the polishing pad 110 may receive the slurry S which is provided while the CMP process is performed. In some example embodiments, for rapid exchange of chemicals in the CMP process, the porous structure may have high porosity. For example, the polishing pad 110 may have the porous structure having a high porosity of about 50% to about 80%.

The polishing surface of the polishing pad 110 (e.g., the polishing surface of the polishing layer 112) may include grooves 112_g having a surface in direct contact with the polishing target and a depth therefrom. The polishing pad 110 may include the grooves 112_g having a radial structure extending from the center to the periphery of the polishing pad 110, for rapid exchange of chemicals in the CMP process.

Referring to FIG. 2, the polishing pad 110 may include the grooves 112_g on the polishing surface of the polishing pad 110. The grooves 112_g may be radially disposed on the polishing surface of the polishing pad 110. In some embodiments, the grooves 112_g may be formed in a linear structure extending from the center to the periphery of the polishing pad 110. For example, the polishing pad 110 including the grooves 112_g of the linear structure may include simply yet elaborately placed grooves 112_g to support a uniform flow of slurry. The grooves 112_g may be symmetrically arranged with respect to the center of the polishing pad 110. The grooves 112_g may be spaced apart from each other by a constant angle.

In FIG. 2, sixteen grooves 112_g arranged radially with respect to the center of the polishing pad 110 and arranged at equal intervals from each other are shown, but the inventive concepts are not limited thereto. The grooves 112_g may be asymmetrically arranged with respect to each other, and the number of grooves 112_g may be variously modified. In addition, the grooves 112_g in the polishing pad 110 may be formed in a curved structure from the center to the periphery of the polishing pad 110, rather than the linear structure.

FIGS. 3 and 4 illustrate a polishing pad 110a having grooves 112_ga and a polishing pad 110b having first and second grooves 112_gc and 112_gb, wherein the grooves 112_ga, 112_gb, and 112_gc are different from the grooves 112_g of the polishing pad 110 of FIG. 2.

Referring to FIG. 3, the polishing pad 110a may include the grooves 112_ga on the polishing surface of the polishing pad 110a. The grooves 112_ga may be formed in a spiral structure extending from the center to the periphery of the polishing pad 110a. For example, the polishing pad 110a including the grooves 112_ga of the spiral structure may induce a natural flow of slurry along the grooves 112_ga. The grooves 112_ga may be symmetrically arranged with respect to the center of the polishing pad 110a. The grooves 112_ga may be spaced apart from each other at regular intervals.

Although the grooves 112_ga of the spiral and radial structure formed symmetrically with respect to the center of the polishing pad 110a are shown in FIG. 3, the inventive concepts are not limited thereto. The grooves 112_ga of the spiral and radial structure may be asymmetrically arranged.

Referring to FIG. 4, the polishing pad 110b may include the first grooves 112_gc and the second grooves 112_gb on the polishing surface of the polishing pad 110b. The first grooves 112_gc may be configured to have a shape of concentric circles that share the center of the polishing pad 110b and are spaced apart from each other. Each of the first grooves 112_gc has a different diameter. In at least one example embodiment, the first grooves 112_gc may be spaced at equal intervals from each other. The second grooves 112_gb may be radially disposed on the polishing surface of the polishing pad 110b as shown in FIG. 2. The second grooves 112_gb may extend from the center to the periphery of the polishing pad 110b and intersect with the first grooves 112_gc. For example, the second grooves 112_gb may be formed in a linear structure extending from the center to the periphery of the polishing pad 110b.

In FIG. 4, the first grooves 112_gc in the shape of concentric circles arranged at regular intervals with respect to the center of the polishing pad 110b and the second grooves 112_gb in the linear structure arranged radially with respect to the center of the polishing pad 110b and arranged at equal intervals with respect to each other are illustrated, but the present invention is not limited thereto. The first grooves 112_gc may be arranged at different intervals with respect to the center of the polishing pad 110b. In addition, the second grooves 112_gb may extend from the center to the periphery of the polishing pad 110b in the curved structure rather than the linear structure, may have a spiral structure, or may be formed asymmetrically with respect to each other.

FIGS. 5A and 5B are cross-sectional views of the polishing pad 110b of FIG. 4. FIG. 5A is a cross-sectional view taken along line A-A′ at a position where the second grooves 112_gb of the radial structure are not formed, and FIG. 5B is a cross-sectional view taken along line A-A″ at a position where the second grooves 112_gb of the radial structure are formed.

Referring to FIGS. 4, 5A, and 5B, the polishing layer 112 located on the support layer 116 may include the first grooves 112_gc located between protrusions 112_p protruding in a vertical direction and the first grooves 112_gc located between the protrusions 112_p. The first grooves 112_gc may be defined as spaces between the protrusions 112_p arranged radially. According to at least one example embodiment, the first grooves 112_gc may also be defined as recesses extending downward from the top surface of the polishing layer 112 in the vertical direction.

The second grooves 112_gb may be defined as spaces between the protrusions 112_p arranged in a circumferential direction. FIG. 5B is a cross-sectional view at an intersection of the first grooves 112_gc and the second groove 112_gb. FIG. 5B illustrates that the depth of the first groove 112_gc is greater than the depth of the second groove 112_gb, and the height of the second groove 112_gb in FIG. 5B is less than that in FIG. 5A. However, the inventive concepts are not limited thereto. The depths of the first groove 112_gc and the second groove 112_gb may be the same (or substantially similar) or the depth of the first groove 112_gc may be less than the depth of the second groove 112_gb.

Referring back to FIG. 1, the CMP device 10 may include the slurry port 130 for supplying the slurry S for polishing to the polishing pad 110, according to some embodiments. The slurry port 130 may be arranged adjacent to the polishing pad 110. For example, the slurry port 130 may be arranged above the polishing pad 110 and configured to discharge the slurry S toward the top surface of the polishing pad 110. The composition of the slurry S is described below.

Although the slurry port 130 is briefly illustrated in FIG. 1, the slurry port 130 may include a slurry source for storing the slurry S, a slurry arm, a slurry supply nozzle connected to one end of the slurry arm, and/or the like. The slurry S provided from the slurry source may be provided to the slurry supply nozzle through a flow path, and the slurry supply nozzle may dispense the slurry S onto the top surface of the polishing pad 110. The slurry arm may be configured to rotate about a rotation axis in the vertical direction and may be configured to perform a sweeping motion with respect to the rotation axis. The slurry arm may be configured to perform the sweeping motion while the slurry S is dispensed from the slurry supply nozzle. The slurry S provided from the slurry source may be accommodated in the grooves 112_g of the polishing pad 110.

The carrier head 140 may be arranged adjacent to the polishing pad 110. The carrier head 140 may be loaded onto the wafer W. The carrier head 140 may provide the wafer W onto the polishing pad 110. When the wafer W loaded onto the carrier head 140 is positioned to face the platen 120, the carrier head 140 may be configured to rotate while pressing the wafer W toward the platen 120. Although only one carrier head 140 on the polishing pad 110 is shown in FIG. 1, a plurality of carrier heads 140 may be disposed on the polishing pad 110. The carrier head 140 may be configured to control the pressure applied to the wafer W.

In some example embodiments, the carrier head 140 may include a retaining ring 142 for holding the wafer W below a flexible membrane. The carrier head 140 defined by the flexible membrane may include a plurality of pressurizable chambers which are independently controllable. The pressurizable chambers may apply independently controllable pressure to relevant and/or selected regions on the flexible membrane and/or relevant and/or selected regions on the wafer W. The pressurizable chambers may be configured to apply a positive pressure to the wafer W to hold the wafer W against the retaining ring 142, and/or to apply a negative pressure to the wafer W to hold the wafer W using vacuum pressure.

The carrier head 140 may be supported by a support structure 150. The carrier head 140 may be connected to a carrier head rotation motor 154 through a drive shaft 152 of the support structure 150 and may be rotated about a central axis 155 of the drive shaft 152. For example, the support structure 150 may include, but is not limited to, a carousel or a track. In some embodiments, the carrier head 140 may translate laterally across the top surface of the polishing pad 110. For example, the carrier head 140 may be vibrated on a slider of the support structure 150 or by rotational vibration of the support structure 150.

The polishing pad conditioner 160 may be arranged adjacent to the polishing pad 110. The polishing pad conditioner 160 may be arranged on top of the polishing pad 110 and configured to polish the polishing pad 110. The polishing pad conditioner 160 may be configured to perform a conditioning process to maintain the performance of the polishing pad 110 and optimize the polishing efficiency. The polishing pad conditioner 160 may restore the surface roughness of the polishing pad 110 with a smooth surface and blocked pores during the polishing process, thereby improving the distribution of the slurry S and maintaining the uniform polishing performance. In addition, the polishing pad conditioner 160 may be configured to perform a dressing process to keep the surface of the polishing pad 110 flat.

According to at least one example embodiment, the polishing pad conditioner 160 may have a high surface roughness average (Ra) to overcome a step difference between copper and a polymer among components on the wafer W that is the polishing target and to selectively polish the surface of copper. For example, the polishing pad conditioner 160 may have a high Ra of about 100 μm to about 350 μm.

Referring to FIG. 6, the polishing pad conditioner 160 may include a conditioner support plate 162, an abrasive crystal support plate 164, and abrasive crystals 166.

According to at least one example embodiment, the conditioner support plate 162 may support other components of the polishing pad conditioner 160. The conditioner support plate 162 may evenly distribute the pressure and the rotational force applied to the polishing pad conditioner 160 during the polishing process so that the abrasive crystals 166 are uniformly in contact with the polishing pad 110.

The abrasive crystal support plate 164 may fix the abrasive crystals 166. The abrasive crystal support plate 164 may be configured to place the abrasive crystals 166 at an appropriate angle and an appropriate location to increase the contact efficiency with polishing pad 110. The abrasive crystal support plate 164 may disperse the pressure which is generated when the abrasive crystals 166 are in contact with the polishing pad 110 to maintain the wear uniformity.

The abrasive crystals 166 may scrape or roughen the surface of the polishing pad 110 to restore the texture thereof. The abrasive crystals 166 may polish the surface of the polishing pad 110 to open the blocked pores of the polishing pad 110 during the polishing process, thereby allowing the slurry S to penetrate into the polishing pad 110. In addition, the abrasive crystals 166 may compensate for the uneven wear of the polishing pad 110 to enable the uniform polishing.

The abrasive crystals 166 may be fixed to the abrasive crystal support plate 164 in an aligned pattern. For example, the abrasive crystals 166 may be arranged in a grid shape or a radial shape and fixed to the abrasive crystal support plate 164. Alternatively, the abrasive crystals 166 may also be arranged randomly and fixed to the abrasive crystal support plate 164.

According to at least one example embodiment, the abrasive crystals 166 may have an octahedral shape. The abrasive crystals 166 may protrude from a surface of the polishing pad conditioner 160, that is, a surface of the abrasive crystal support plate 164. For example, one edge of the abrasive crystal 166 may be formed to have a length s of about 100 micrometers (μm) to about 350 μm to maintain the high roughness and consistency of the polishing pad 110.

Referring again to FIG. 1, the CMP device 10 may further include a control system for controlling the CMP device 10. For example, the control system may control the rotation of the platen 120, the supply of the slurry S, the position of the carrier head 140, and/or the like. The control system may include a controller 190, such as a general-purpose programmable digital computer, an output device 192, such as a monitor, and an input device 194, such as a keyboard. Although FIG. 1 shows a configuration in which the control system is connected only to the motor 121, this is only an example. The control system may also be connected to the carrier head 140 to adjust the pressure or the rotational speed of the carrier head 140. The control system may also be connected to the slurry port 130 to regulate the supply of the slurry S. The control system and/or the controller 190 may include processing circuitry, such as hardware, software, and/or a combination of hardware and software. For example, the processing circuitry may include, but is not limited to, a central processing unit (CPU), an application processor (AP), an arithmetic logic unit (ALU), a graphic processing unit (GPU), a digital signal processor, a microcomputer, a field programmable gate array (FPGA), a System-on-Chip (SoC) a programmable logic unit, a microprocessor, or an application-specific integrated circuit (ASIC), etc.

In addition, the CMP device 10 may further include configurations that can be understood by those skilled in the art. For example, the CMP device 10 may further include a temperature controller and a temperature adjuster.

The temperature controller (not illustrated) may control a polishing temperature at which the polishing process for the wafer W is performed. For example, the temperature controller may be connected to the platen 120 to heat or cool the temperature of the polishing pad 110 disposed on the platen 120. Alternatively, for example, the temperature controller may be connected to the slurry port 130 to heat or cool the temperature of the slurry S supplied from the slurry port 130.

The temperature adjuster (not illustrated) may be spaced apart from the slurry port 130 arranged above the polishing pad 110 or may be arranged in front of the slurry port 130. The temperature adjuster may be configured to adjust the surface temperature of the polishing pad 110 by dispensing the temperature-regulating fluid onto the top surface of the polishing pad 110.

The slurry S used in the CMP device 10 according to various embodiments may be configured to selectively polish copper among polishing targets including copper and a polymer. According to some example embodiments, the slurry S may include abrasive particles, an oxidizing agent, an amino acid complexing agent, deionized water, a cationic chemical, a pH adjuster, a biocide, and/or the like.

The abrasive particles contained in the slurry S may polish the surface of copper during the polishing process. In some embodiments, the slurry S may include 1% or less of abrasive particles to reduce and/or minimize polishing of the polymer among copper and polymer. For example, in at least some example embodiments, the abrasive particles may comprise 1 percent by weight (wt %) or less of the total amount of components in the slurry S and/or 1 percent by volume or less of the total volume of the slurry. The abrasive particles may include monodisperse abrasive particles having a uniform particle size to minimize damage to the surface of the polymer. For example, the abrasive particles may include the monodisperse abrasive particles having a polydispersity index (PDI) of 0.1 or less. The abrasive particles may include the monodisperse abrasive particles having an average particle size of about 1 nanometers (nm) to about 50 nm.

In some example embodiments, the abrasive particles may include inorganic oxidized abrasive particles. For example, the abrasive particles may include silica (SiO₂), alumina (Al₂O₃), zirconia-ceria, or a combination thereof. However, the abrasive particles are not limited thereto. The abrasive particles may include ceria, (CeO₂), titania (TiO₂), zirconia (ZrO₂), magnesia (MgO), germania (GeO2), mangania (MnO₂), a combination thereof, and/or the like, in addition to the foregoing materials.

The oxidizing agent contained in the slurry S oxidizes the surface of metal so that the abrasive particles can easily remove oxides. Depending on the reaction conditions and the concentration of the oxidizing agent, only a certain metal or layer may be selectively oxidized. In at least one example embodiment, the oxidizing agent may selectively oxidize the surface of copper. In some embodiments, 5 percent by weight (wt %) or less of the oxidizing agent may be included in the slurry S for selective polishing the copper.

Non-limiting examples of the oxidizing agent contained in the slurry S may include organic peroxides (such as peracetic acid, perbenzoic acid, tert-butyl hydroperoxide, and/or the like); permanganic acid compounds (such as potassium permanganate and/or the like); dichromic acid compounds (such as potassium dichromate and/or the like); halogen acid compounds (such as potassium iodate and/or the like); nitric acid compounds (such as nitric acid, iron nitrate, and/or the like); perhalogen acid compounds (such as perchloric acid and/or the like); persulfates (such as sodium persulfate, potassium persulfate, ammonium persulfate and/or the like); percarbonate salts (such as sodium percarbonate and potassium percarbonate; urea peroxide; heteropoly acids and/or the like); a combination thereof; and/or the like. Due to the higher reactivity with conductive materials in the polishing target (e.g., compared to, for example, a photoresist material in a photoresist pattern (described in further detail below)) the oxidizing agent promotes the chemical polishing of the conductive material over the photoresist material, thereby facilitating the selective polishing of the polishing target with respect to the photoresist pattern.

An amino acid complexing agent contained in the slurry S may be selected to bind to the metal ion generated by the oxidizing agent to form a stable complexing agent (or “chelated agent”). The amino acid complexing agent may include, for example, glycine, alanine, glutamic acid, and/or the like. In some embodiments, 5% or less of the amino acid complexing agent may be included in the slurry S for selectively polishing copper. Due to the greater stability (e.g., affinity) of the stable complexing agent, the metal ion may be hindered and/or prevented from reattaching to the metal, and/or may be rendered electrochemically neutral, thereby facilitating the removal of the metal ions from the polishing target, thereby facilitating the selective polishing of the polishing target with respect to the photoresist pattern.

The deionized water contained in the slurry S may function as a basic medium of the slurry S to uniformly disperse other components and facilitate chemical reactions. For example, the deionized water may include pure water. The amount of the deionized water included in the slurry S is not particularly limited. The deionized water may be included as the balance together with the main components including metal ions, a cationic chemical, a nonionic polymer, abrasive particles, a pH adjuster, and/or the like in the slurry S.

In some example embodiments, the slurry S may include a cationic chemical that reduces and/or prevents dishing to excessively polish and deform the surface of copper into a grooved or concave shape. The cationic chemical included in the slurry S may include a water-soluble cationic chemical. For example, the cationic chemical may include an amphoteric amino acid, an amine group, a combination thereof, and/or the like. The amphoteric amino acid may include, e.g., lysine, methionine, glycine, arginine, a combination thereof, and/or the like. The amine group may include, for example, aminobutyric acid, 4-amino benzoic acid, picolinic acid, 1,2,4-triazole, benzotriazole, a combination thereof, and/or the like.

The pH adjuster included in the slurry S may adjust the slurry S to have a pH selected from the range of about 2 to about 11.

In some example embodiments, the pH adjuster may include, but is not limited to, potassium hydroxide, acetic acid, nitric acid, hydrogen chloride, ammonium hydroxide, sodium hydroxide, tetramethylammonium hydroxide, a combination thereof, and/or the like.

The biocide contained in the slurry S may protect against (e.g., reduce, mitigate, and/or prevent) the slurry S and/or the polishing target from being contaminated with microorganisms. In at least one example embodiment, the biocide may include, but is not limited to, organo-tin compounds, salicylanilide, formaldehyde, quaternary ammonium compounds, 2-bromo-2-nitropropane-1,3-diol (bronopol), 2,2-dibromo-3-nitrilopropionamide (DBNPA), isothiazolone, carbamate, quaternary phosphonium salts (e.g., tetrakis (hydroxymethyl)-phosphonium sulfate (THPS)), sodium chloride, sodium hypochlorite, trichloroisocyanuric acid, dichloroisocyanuric acid, calcium hypochlorite, lithium hypochlorite, chlorine dioxide, ozone, hydrogen peroxide, a combination thereof, and/or the like.

When the slurry S includes the biocide, the amount of the biocide may be about 0.001 wt % to about 10 wt % based on the total amount of components in the slurry S. In at least one example embodiment, the amount of the biocide may be from about 0.001 wt % to about 5 wt %, from about 0.001 wt % to about 3 wt %, or from about 0.001 wt. % to about 1 wt. %, based on the total amount of slurry S.

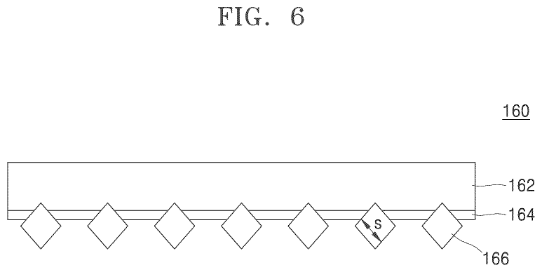

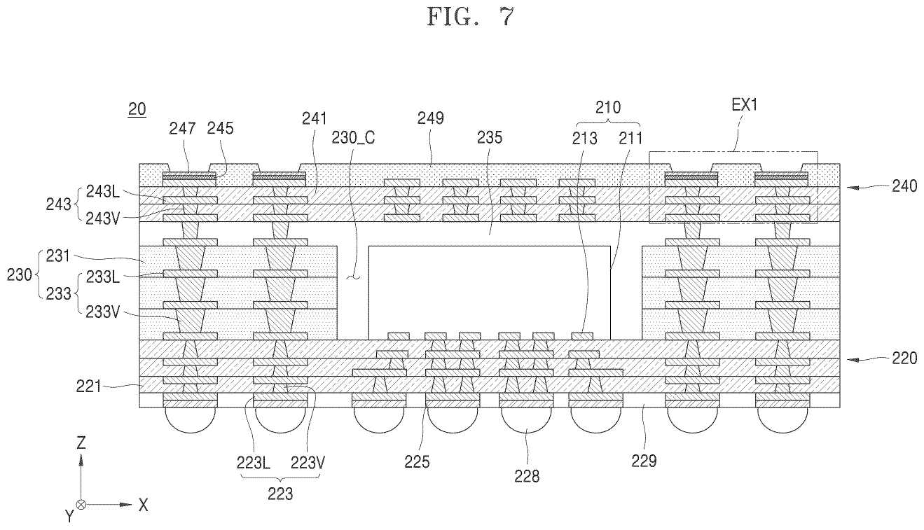

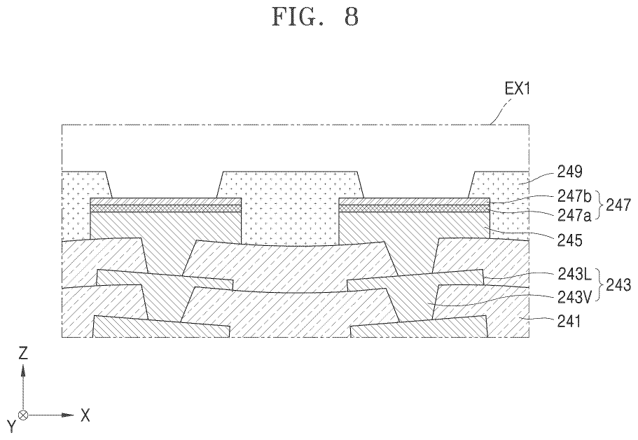

FIG. 7 is a schematic cross-sectional view of a semiconductor package 20 according to at least one example embodiment. FIG. 8 is an enlarged cross-sectional view schematically illustrating portion EX1 in FIG. 7.

Referring to FIGS. 7 and 8, the semiconductor package 20 may include a semiconductor chip 210, a first redistribution structure 220, a connection structure 230, and a second redistribution structure 240.

Hereinafter, unless otherwise specified, a direction parallel to the top surface of the first redistribution structure 220 is defined as a first horizontal direction (X direction), a direction perpendicular to the top surface the first redistribution structure 220 is defined as a vertical direction (Z direction), and a direction perpendicular to both the first horizontal direction (X direction) and the vertical direction (Z direction) is defined as a second horizontal direction (Y direction).

The connection structure 230 of the semiconductor package 20 may be disposed on the first redistribution structure 220. For example, the connection structure 230 may be electrically connected to a portion of a first redistribution pattern 223 of the first redistribution structure 220. The connection structure 230 may electrically connect the second redistribution structure 240 to the first redistribution structure 220.

The connection structure 230 may include and/or define a cavity 230_C extending from a top surface to a bottom surface of the connection structure 230. The semiconductor chip 210 may be mounted inside the cavity 230_C of the connection structure 230. The cavity 230_C may be formed at the center of the connection structure 230 as shown in FIG. 7. However, the number and arrangement of cavities 230_C are not limited thereto.

The connection structure 230 may include a plurality of base layers 231 and a via structure 233. In some embodiments, the plurality of base layers 231 may include a first base layer, a second base layer, and/or a third base layer stacked in the vertical direction (Z direction). For example, the connection structure 230 may include a multilayer structure including the first base layer to the third base layer. The plurality of base layers 231 may surround at least a portion of the via structure 233.

In some embodiments, the plurality of base layers 231 may each include a thermosetting resin, such as a phenol resin or an epoxy resin, a thermoplastic resin such as polyimide, an insulating material impregnated with at least one resin selected therefrom into a core made of an inorganic filler and/or glass fiber, a combination thereof, and/or the like.

For example, the plurality of base layers 231 may each include a prepreg, an Ajinomoto build-up film (ABF), a frame retardant 4 (FR4 ), a tetrafunctional epoxy, a polyphenylene ether, a bismaleimide triazine (BT), an epoxy/polyphenylene oxide, a Thermount, a cyanate ester, a polyimide, a liquid crystal polymer, a combination thereof, and/or the like.

The via structure 233 may include a plurality of connection pads 233L and a plurality of connection vias 233V. The plurality of connection pads 233L may extend in the horizontal direction (X direction and/or Y direction) on the top surface or the bottom surface of each of the plurality of base layers 231.

In some example embodiments, the plurality of connection pads 233L may include first to fourth connection pads located at different vertical levels. The first connection pads at the bottom of the plurality of connection pads 233L may be connected to the first redistribution structure 220. The fourth connection pads located at the top of the plurality of connection pads 233L may be connected to the second redistribution structure 240.

The plurality of connection vias 233V may extend in the vertical direction (Z direction) inside the plurality of base layers 231. The plurality of connection vias 233V may connect the plurality of connection pads 233L located at different vertical levels. In some embodiments, the plurality of connection vias 233V may include first to third connection vias located at different vertical levels.

In some embodiments, the plurality of connection pads 233L may each include electrolytically deposited (ED) copper foil, rolled-annealed (RA) copper foil, stainless steel foil, aluminum foil ultra-thin copper foil, sputtered copper, or copper alloys. In some embodiments, the plurality of connection vias 233V may each include copper, nickel, stainless steel, beryllium copper, a combination thereof, and/or the like.

The semiconductor chip 210 of the semiconductor package 20 may be disposed on the first redistribution structure 220. The semiconductor chip 210 may be mounted in the cavity 230_C of the connection structure 230 and may be spaced from an inner wall of the cavity 230_C. Although the semiconductor package 20 is illustrated as including one semiconductor chip 210 in FIG. 7, the number of semiconductor chips 210 is not limited thereto.

In some example embodiments, the semiconductor chip 210 may include a logic chip and/or a memory chip. The logic chip may include a microprocessor. For example, the logic chip may include a central processing unit (CPU), a controller, an application-specific integrated circuit (ASIC), or the like. The memory chip may include a volatile memory chip, such as dynamic random-access memory (DRAM) or static random-access memory (SRAM), or a nonvolatile memory chip, such as phase-change random-access memory (PRAM), magneto-resistive random-access memory (MRAM), ferroelectric random-access memory (FeRAM), or resistive random-access memory (RRAM).

The semiconductor chip 210 may include a semiconductor substrate 211 and a chip pad 213. In some embodiments, the semiconductor substrate 211 may include silicon (Si). In addition, the semiconductor substrate 211 may include a semiconductor element, such as germanium (Ge), or a compound semiconductor, such as silicon carbide (SiC), gallium arsenide (GaAs), indium arsenide (InAs), and indium phosphide (InP).

The chip pad 213 may be disposed on a bottom surface of the semiconductor substrate 211. The chip pad 213 may be electrically connected to various types of individual components included in the active surface of the chip pad 213. In addition, the chip pad 213 may be electrically connected to at least a portion of a top first via pattern 223V among a plurality of first via patterns 223V of the first redistribution structure 220.

The first redistribution structure 220 of the semiconductor package 20 may extend input/output terminals of the semiconductor chip 210 to an outer region of the first redistribution structure 220. The first redistribution structure 220 may include a plurality of first insulating layers 221 and the first redistribution pattern 223.

The first insulating layers 221 may include an insulating material, for example, a photo imageable dielectric (PID) resin. In these cases, the first insulating layers 221 may further include an inorganic filler. The first insulating layers 221 may include the same or different materials.

The first redistribution pattern 223 may include a first via pattern 223V and a first line pattern 223L. The first line pattern 223L may be disposed on at least one of a top surface and a bottom surface of the first insulating layers 221. The first via pattern 223V may pass through the first insulating layers 221 and may be connected to some of the first line patterns 223L. The number and arrangement of first insulating layers 221, first via patterns 223V, and first line patterns 223L constituting the first redistribution structure 220 are not limited to those shown in the drawings and may be variously modified in embodiments.

The first redistribution pattern 223 may include a conductive material, for example, copper (Cu), aluminum (Al), silver (Ag), tin (Sn), gold (Au), nickel (Ni), lead (Pb), titanium (Ti), an alloy thereof, and/or the like.

The bottom surface of the semiconductor chip 210 may be in direct contact with top first insulating layers 221 among the first insulating layers 221. The first redistribution pattern 223 may extend the input/output terminals of the semiconductor chip 210 to the outside. That is, the semiconductor package 20 may include a fan-out semiconductor package.

In some example embodiments, the first redistribution structure 220 may be formed on the bottom surface of the semiconductor chip 210 by a chip-first process. According to the order in which the first redistribution structure 220 is formed, the first via pattern 223V may have a tapered shape where the horizontal width of the first via pattern 223V increases as the distance from the semiconductor chip 210 increases.

In some example embodiments, the semiconductor package 20 may further include a first passivation layer 229. The first passivation layer 229 may be disposed on a bottom surface of the first redistribution structure 220 and may protect the first redistribution structure 220. The first passivation layer 229 may include an insulating material and may include, but not limited to, e.g., a thermosetting resin or a thermoplastic resin.

For example, at least a portion of the first line pattern 223L may be exposed through openings in the first passivation layer 229. The exposed first line pattern 223L may be electrically connected to the first pads 225 inside the openings. External connection terminals 228 may be electrically connected to the first pads 225, respectively.

The external connection terminals 227 may connect the semiconductor package 20 to a mainboard of a separate electronic device on which the semiconductor package 20 is mounted. The external connection terminals 227 may include a conductive material, for example, at least one of solder, Sn, Ag, Cu, and Al. The shape of the external connection terminals 227 may be changed to various shapes, such as a land, a bump, a pillar, and a pin, in addition to a ball shape.

A molding layer 235 of the semiconductor package 20 may be arranged to fill a space between the connection structure 230 and the semiconductor chip 210 in the cavity 230_C and may cover the top surface of each of the connection structure 230 and the semiconductor chip 210.

The molding layer 235 may include an insulating material, such as an epoxy-based material, a thermoset material, a thermoplastic material, or the like. For example, the molding layer 235 may include ABF, FR-4, BT, epoxy molding compound (EMC), and/or the like.

The second redistribution structure 240 of the semiconductor package 20 may be arranged above the connection structure 230 and the semiconductor chip 210. The second redistribution structure 240 may include second insulating layers 241, a second redistribution pattern 243, a bump pad 245, a metal pad 247, and a second passivation layer 249.

The second insulating layers 241 may include an insulating material, for example, a PID resin. In these cases, the second insulating layers 241 may further include an inorganic filler. The second insulating layers 241 may include the same or different materials.

The second redistribution pattern 243 may include a second via pattern 243V and a second line pattern 243L. The second line pattern 243L may be disposed on at least one of a top surface and a bottom surface of the second insulating layer 241. The second via pattern 243V may extend in the vertical direction (Z direction) inside the second insulating layer 241 or inside the molding layer 235. The second via pattern 243V may connect the second line patterns 243L located at different vertical levels or may connect at least a portion of the bottom second line pattern 243L to at least a portion of the top connection pad 233L of the connection structure 230. In some embodiments, the second via pattern 243V may have a tapered shape where the horizontal width of the second via pattern 243V increases as the distance from the top surface of the semiconductor chip 210 increases. The number and arrangement of second insulating layers 241, second via patterns 243V, and second line patterns 243L constituting the second redistribution structure 240 are not limited to those shown in the drawings, and may be variously modified in the embodiments.

In some example embodiments, the second redistribution pattern 243 may include a conductive material, such as Cu, titanium (Ti), titanium tungsten (TiW), titanium nitride (TiN), tantalum (Ta), tantalum nitride (TaN), chromium (Cr), Al, indium (In), molybdenum (Mo), manganese (Mn), cobalt (Co), Sn, nickel (Ni), magnesium (Mg), rhenium (Re), beryllium (Be), gallium (Ga), ruthenium (Ru), a combination thereof, and/or the like.

The bump pad 245 may be disposed on a top surface of the second insulating layer 241. The bump pad 245 may be disposed on the second redistribution pattern 243 and may be electrically connected to the second redistribution pattern 243. For example, the bump pad 245 may be connected to the top second via pattern 243V among the second via patterns 243V.

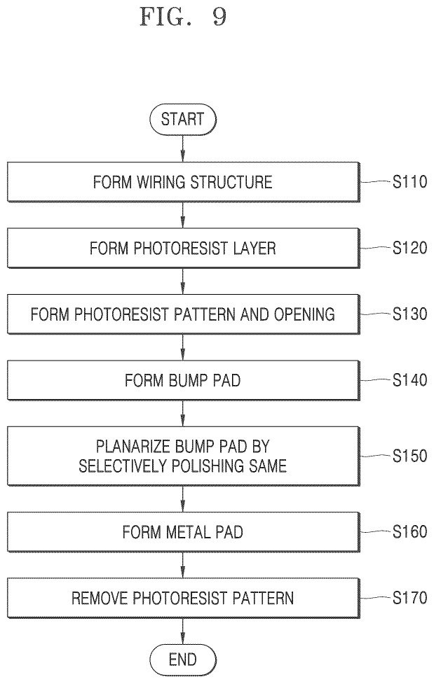

A plurality of bump pads 245 may be disposed on the top surface of the second insulating layer 241. In these cases, the top surface of each of the bump pads 245 may be formed to be flat. For example, the top surface of each of the bump pads 245 may be formed to be coplanar. The undulation may occur when the second redistribution structure 240 includes the plurality of second insulating layers 241 and the second redistribution pattern 243 between the second insulating layers 241. For example, as the number of stacks formed of the second insulating layer 241 and the second redistribution pattern 243 increases, the undulation may occur on the top surface of the second insulating layer 241. The bump pads 245 disposed on the top surface of the second insulating layer 241 where the undulation has occurred may have bottom surfaces that are not horizontal to each other. However, the top surfaces of the bump pads 245 may be planarized to be horizontal to each other. A method of planarizing each of the bump pads 245 is described below with reference to FIGS. 9 and 10 to 16.

The bump pads 245 may include a conductive material, such as Cu. However, the inventive concepts are not limited thereto. The bump pads 245 may include the same material as the second redistribution pattern 243.

The metal pad 247 may be disposed on the bump pad 245. The metal pad 247 may be in contact with a top surface of the bump pad 245. The metal pad 247 may include a double structure including a first metal pad 247a and a second metal pad 247b disposed on the first metal pad 247a. The first metal pad 247a and the second metal pad 247b may include Ni and Au, respectively, but are not limited thereto.

The second passivation layer 249 may be disposed on the top surface of the second insulating layer 241. The second passivation layer 249 may protect the second insulating layer 241, the second redistribution pattern 243, the bump pad 245, and the metal pad 247. The second passivation layer 249 may include an insulating material. For example, the second passivation layer 249 may include, but is not limited to, ABF, FR-4, BT, EMC, and the like.

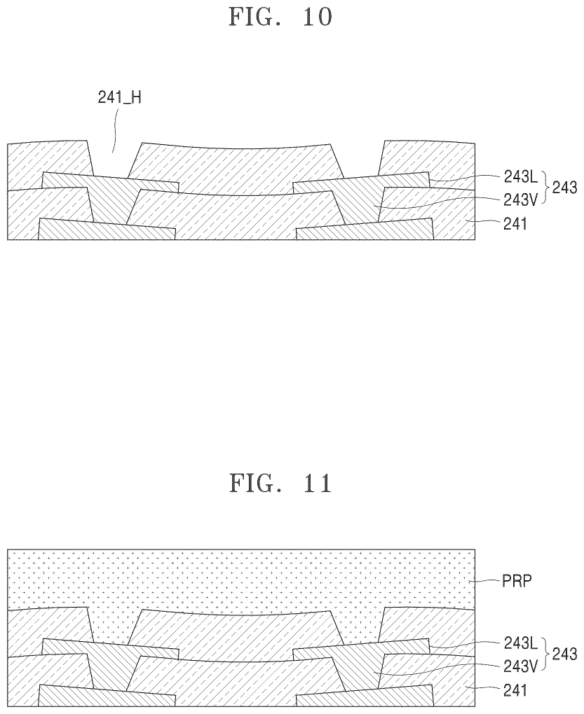

FIG. 9 is a flowchart of a method of manufacturing the semiconductor package 20, according to at least one example embodiment. FIGS. 10 to 16 are diagrams schematically illustrating the method of manufacturing the semiconductor package 20, according to at least one example embodiment. FIGS. 10 to 16 partially show a process of forming the bump pad 245 and the metal pad 247 during a semiconductor package manufacturing process. In particular, the method of planarizing the surface of the bump pad 245 where the undulation occurs as the number of stacks increases is mainly described.

Referring to FIG. 9 and FIG. 10, first, a wiring structure is formed in operation S110. The wiring structure may refer to the second redistribution structure 240 in FIG. 7. The second insulating layer 241 where a plurality of holes 241_H are formed may be disposed on a top layer of the second redistribution structure 240. For example, in at least some embodiments, the second insulating layer 241 may be formed by selectively developing the second insulating layer 241 to include the plurality of holes 241_H, and removing uncured (and/or undeveloped) material from the plurality of holes 241_H.

When the undulation occurs on the surface of the second insulating layer 241 during the semiconductor package manufacturing process, the plurality of holes 241_H may also be formed along the surface of the second insulation layer 241 so as not to be parallel to each other. For example, as the number of stacks increases in the second redistribution structure 240 including a plurality of layers, the undulation may occur on the surface of the upper second insulating layer 241, as shown in FIG. 10.

Referring to FIG. 9 and FIG. 11, a photoresist layer PR is formed on the second insulating layer 241 in operation S120. The photoresist layer PR is a photosensitive material used to form a fine pattern. When exposed to light (e.g., ultraviolet light or laser), the chemical properties of the photoresist layer PR may be changed and the photoresist layer PR may be selectively removed in the subsequent process. The photoresist layer PR may include a composite material including a polymer.

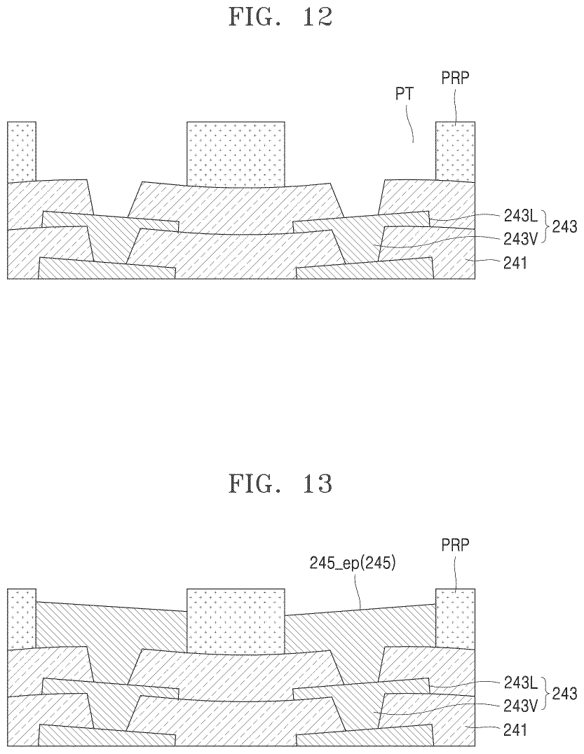

Referring to FIG. 9 and FIG. 12, a plurality of photoresist patterns PRP are formed in operation S130. The photoresist layer PR (see FIG. 11) in the result of FIG. 11 is exposed and developed to form the photoresist patterns PRP and openings PT between the photoresist patterns PRP. The openings PT may be formed to overlap with the holes 241_H (see FIG. 10) of the second insulating layer 241, respectively. In other words, the photoresist pattern PRP may be formed such that the openings PT are formed in the holes 241_H of the second insulating layer 241.

Referring to FIGS. 9 and 13, the bump pads 245 are formed in operation S140. Fo example, the opening PT between the photoresist patterns PRP may be electroplated with copper to form the bump pad 245. Each of bump pad plating layers 245_ep may be formed between the photoresist patterns PRP. The bump pad plating layers 245_ep may be formed to partially or completely fill the openings PT between the hole 241_H (see FIG. 10) of the second insulating layer 241 and the photoresist pattern PRP. The undulation may be formed on the top surface of the second insulating layer 241 so that the bump pad plating layers 245_ep are formed at different heights. For example, the bump pad plating layer 245_ep may be formed to have a top surface parallel to the top surface of the second insulating layer 241 so that the top surfaces of the bump pad plating layers 245_ep are not parallel to each other.

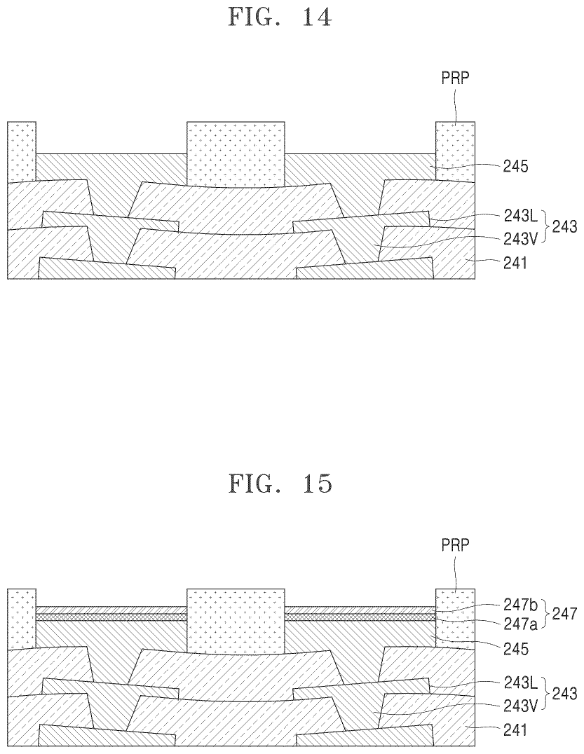

Referring to FIG. 9 and FIG. 14, the surfaces of the bump pad plating layers 245_ep are polished in operation S150. For example, the surfaces of the bump pad plating layers 245_ep including copper may be polished by using the CMP device 10 described with reference to FIGS. 1 to 6. For example, using the CMP device 10, only copper may be selectively polished without polishing the photoresist pattern PRP including the polymer material. Hereinafter, the bump pads 245 may be understood as the bump pad plating layers 245_ep.

According to at least one example embodiment, the bump pads 245 may be polished using the polishing pad composed of a porous structure to selectively polish only the bump pads 245 with respect to the photoresist pattern PRP. For example, the polishing pad may have a porous structure having a high porosity of about 50% to about 80%. For example, the bump pad 245 may be polished using the polishing pad having grooves radially arranged in the surface of the bump pad 245 for rapid chemical exchange. In these cases, the radially arranged grooves may also be referred to as “radial grooves”.

According to at least one example embodiment, to maintain the surface roughness of the polishing pad, the polishing pad may be polished by the polishing pad conditioner. The polishing pad conditioner may have a high Ra to overcome the step difference between the bump pad 245 and the photoresist pattern PRP and may selectively polish the surface of the bump pad 245. For example, a plurality of abrasive crystals may be formed in an octahedral shape on an outer surface of the polishing pad conditioner. For example, for consistency and high roughness of the polishing pad, one edge of the abrasive crystal in the octahedral shape may be formed to have a length of about 100 μm to about 350 μm.

According to at least one example embodiment, the bump pads 245 may be polished using a slurry containing 1 wt % or less of monodisperse abrasive particles having a PDI of 0.1 or less to minimize polishing of the photoresist patterns PRP and selectively polish only the bump pads 245. For example, the slurry containing the abrasive particles having an average particle size of about 1 nm to about 50 nm may be used in the polishing process. In addition, during the polishing process, the slurry including 5 wt % or less of the oxidizing agent and 5 wt % or less of the amino acid complexing agent may be used to selectively polish only the bump pad plating layer 245_ep with respect to the photoresist pattern PRP.

As a result of the polishing, the bump pads 245 may be uniform in height. For example, the bump pads 245 may be formed at the same (or a substantially similar) height. In addition, each of the bump pads 245 may be formed to have top surfaces that are parallel to each other.

Referring to FIG. 9 and FIG. 15, the photoresist pattern PRP remaining after polishing the surface of the bump pad 245 in operation S160 may be used as a mask to sequentially form the first metal pad 247a and the second metal pad 247b. For example, the first metal pad 247a may include Ni and the second metal pad 247b may include Au.

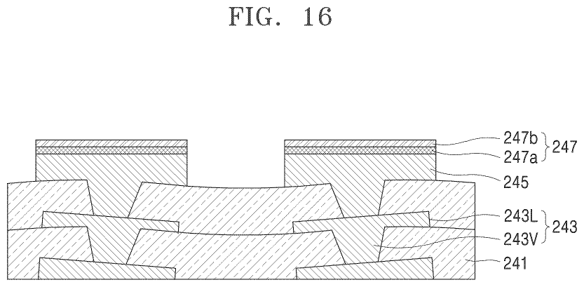

Referring to FIGS. 9 and 16, in operation S170, the photoresist pattern PRP (see FIG. 15) may be removed to form the bump pad 245, the first metal pad 247a, and the second metal pad 247b. Although the second insulating layer 241 has an undulated surface, the structure of the photoresist pattern PRP may not be deformed and only copper may be selectively polished, thereby minimizing height deviation of the bump pad 245.

In the result of FIG. 16, the second passivation layer 249 may be formed on the second redistribution structure 240 to form the semiconductor package 20 of FIG. 7. In addition, although not shown, another semiconductor package or semiconductor chip may be disposed on the planarized bump pad 245 to be electrically connected thereto.

In FIGS. 7 to 16, the method of planarizing the bump pad 245 by selectively polishing only the top surface of the bump pad 245 when forming the bump pad 245 disposed on an upper end of the second redistribution structure 240 in the process of manufacturing the semiconductor package 20 including the semiconductor chip 210, the first redistribution structure 220, the connection structure 230, and the second redistribution structure 230 has been described. However, a method of selectively polishing the metal layer is not limited to the semiconductor package 20 having such a structure. In various types of semiconductor package manufacturing processes, the undulation may occur as the number of stacks increases, and when the metal layer is formed on a surface where the undulation has occurred, the metal layer may be selectively polished and planarized in a similar manner.

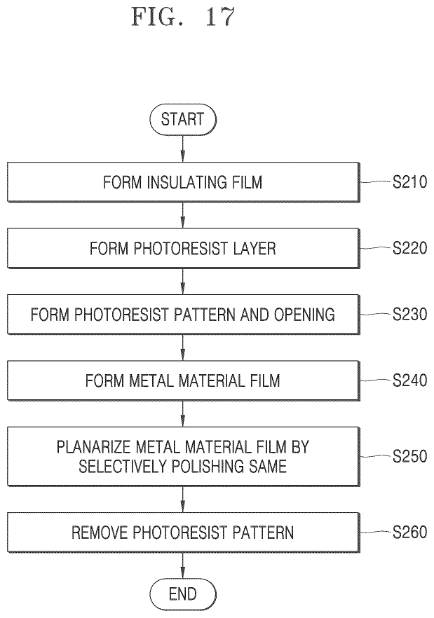

FIG. 17 is a flowchart of a method of manufacturing the semiconductor package, according to at least one example embodiment. FIGS. 18 to 23 are diagrams schematically illustrating the method of manufacturing the semiconductor package. FIGS. 17 to 23 illustrate a method of selectively polishing and planarizing a metal material film when the metal material film is formed on an insulating film in a general process of manufacturing the semiconductor package. For example, the insulating film and the metal material film may mean an insulating layer and a redistribution pattern constituting a redistribution layer.

Referring to FIG. 17 and FIG. 18, an insulating film 310 is first formed in operation S210. For example, the insulating film 310 may include the insulating layer constituting the redistribution layer. The top surface of the insulating film 310 may include the undulation. For example, the insulating film 310 may include a plurality of holes 310_H. In FIG. 18, the holes 310_H are shown to be recessed from the top surface toward the bottom surface of the insulating film 310, but this is only an example. The holes 310_H may extend from the top surface to the bottom surface of the insulating film 310 and pass through the insulating film 310. When the undulation occurs on the surface of the insulating film 310 during the semiconductor package manufacturing process, the holes 310_H may also be formed along the surface of the insulation film 310 so as not to be parallel to each other. For example, as the number of stacks increases in the redistribution layer including a plurality of layers, the undulation may occur on the surface of the upper insulating film 310, as shown in FIG. 18.

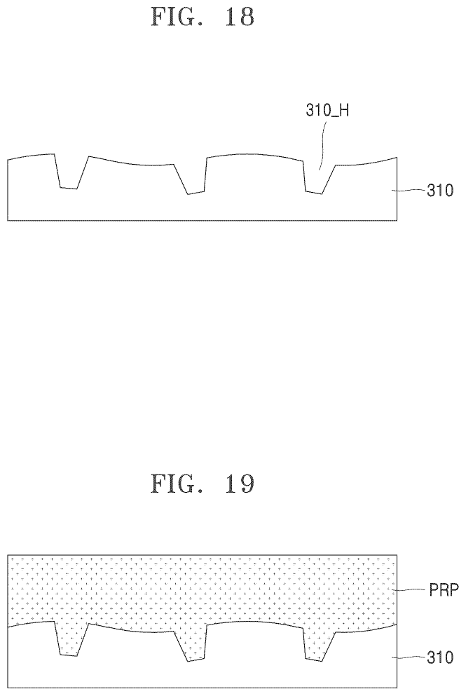

Referring to FIG. 17 and FIG. 19, the photoresist layer PR is formed on the insulating film 310 in operation S220. The photoresist layer PR may include a photosensitive material used to form a fine pattern, and when exposed to light (e.g., ultraviolet light or laser), the chemical properties of the photoresist layer PR may be changed and the photoresist layer PR may be selectively removed in the subsequent process. The photoresist layer PR may include a composite material including a polymer.

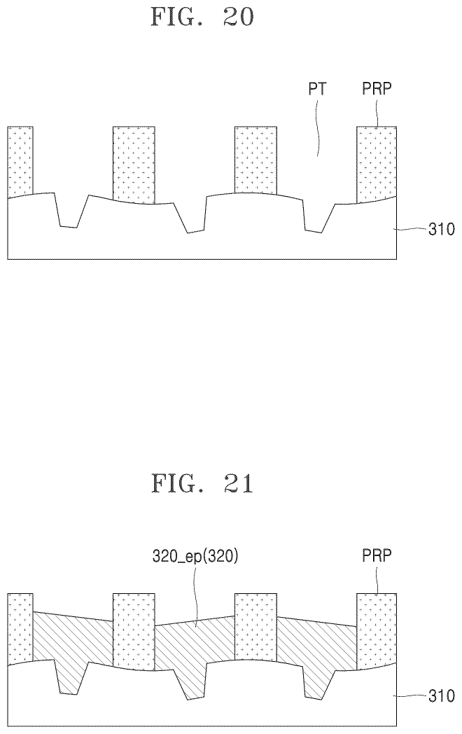

Referring to FIG. 17 and FIG. 20, the plurality of photoresist patterns PRP are formed in operation S230. The photoresist layer PR (see FIG. 19) in the result of FIG. 19 is exposed and developed to form the photoresist patterns PRP and the openings PT each located between the photoresist patterns PRP. The plurality of openings PT may overlap with the holes 310_H (see FIG. 18) of the insulating film 310. In other words, the photoresist patterns PRP may be formed such that the plurality of openings PT are formed in the holes 310_H of the insulating film 310.

Referring to FIG. 17 and FIG. 21, metal material films 320 are formed in operation S240. For example, the metal material films 320 may be formed through electroplating. An electroplating layer 320_ep may be formed between the photoresist patterns PRP. The electroplating layer 320_ep may be formed to fill the opening PT between the hole 310_H (see FIG. 18) of the insulating film 310 and the photoresist pattern PRP. In this case, the undulation may be formed on the top surface of the insulating film 310 so that the electroplating layers 320_ep may be formed at different heights. For example, the electroplating layers 320_ep may be formed to have top surfaces parallel to the top surface of the insulating film 310 so that the top surfaces of the electroplating layers 320_ep are not parallel to each other.

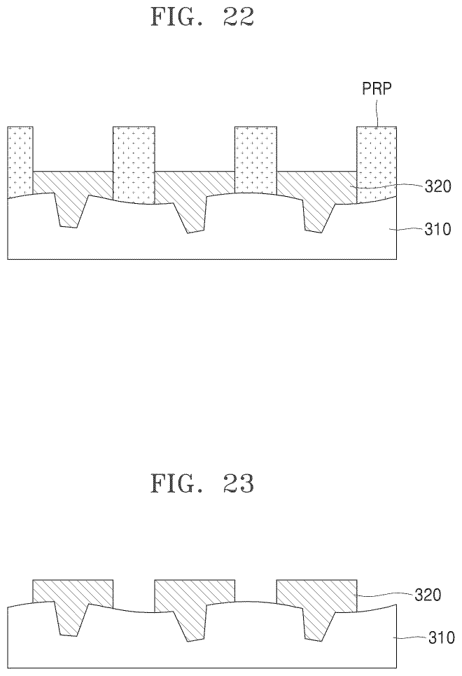

Referring to FIG. 17 and FIG. 22, the surfaces of the electroplating layers 320_ep are polished in operation S250. For example, the surfaces of the electroplating layers 320_ep may be polished using the CMP device 10 described with reference to FIGS. 1 to 6. For example, only the electroplating layer 320_ep may be selectively polished without polishing the photoresist pattern PRP including the polymer material. Hereinafter, the metal material film 320 may be understood as the electroplating layer 320_ep.

According to at least one example embodiment, to selectively polish only the metal material films 320 with respect to the photoresist patterns PRP, the metal material films 320 may be polished using the polishing pad having a porous structure. For example, the polishing pad may have a porous structure having a high porosity of about 50% to about 80%. For example, the metal material film 320 may be polished using the polishing pad including grooves radially arranged in the surface of the polishing pad for rapid chemical exchange.

According to at least one example embodiment, to maintain surface roughness of the polishing pad, the polishing pad may be polished by the polishing pad conditioner. The polishing pad conditioner may have a high Ra to overcome the step difference between the photoresist pattern PRP and the metal material film 320 and selectively polish the surface of the metal material film 320. For example, the plurality of abrasive crystals having the octahedral shape may be formed on an outer surface of the polishing pad conditioner. For example, for consistency and high roughness for the polishing pad, one edge of the abrasive crystal in the octahedral shape may be formed to have a length of about 100 μm to about 350 μm.

According to at least one example embodiment, the metal material films 320 may be polished using the slurry containing 1 wt % or less of monodisperse abrasive particles having a PDI of 0.1 or less to minimize polishing of the photoresist patterns PRP and selectively polish only the metal material films 320. For example, the slurry including the abrasive particles having an average particle size of about 1 nm to about 50 nm may be used in the polishing process. In addition, in the polishing process, the slurry including 5 wt % or less of the oxidizing agent and 5 wt % or less of the amino acid complexing agent may be used to selectively polish only the bump pad plating layer 245_ep with respect to the photoresist pattern PRP.

As a result of polishing, the metal material films 320 may be uniform in height. For example, the metal material films 320 may be formed at the same (or a substantially similar) height. In addition, the metal material films 320 may be formed to have top surfaces parallel to each other.

Referring to FIGS. 17 and 23, in operation S260, the photoresist patterns PRP (see FIG. 15) are removed. The metal material films 320 having the planarized top surfaces may be formed on the undulated insulating film 310.

Using the method of manufacturing the semiconductor package according to at least one example embodiment, a copper pad may be planarized by adjusting a polishing selectivity between a polymer and copper. The copper pad formed on the undulated surface may also be realized to have a height deviation of 100 nm or less through the polishing process. Thus, the quality of the bump pad may be improved and bonding defects may be minimized.

The method of manufacturing the semiconductor package, according to embodiments, may selectively planarize only copper without causing distortion of the photoresist structure, thereby minimizing the planarizing and soldering process. The method of manufacturing the semiconductor package, according to at least one example embodiment, selectively polishes only copper and uses as a mask the photoresist structure that maintains its shape after the polishing process to solder on the planarized copper without a separate exposure process for soldering, thereby enabling the formation of a joint of uniform quality. In addition, after forming the copper pad, subsequent steps, e.g., pad nickel and gold plating, may be performed using the existing mask without additional photo processes, allowing for the production of high-quality products while reducing process costs.

The method of manufacturing the semiconductor package according to at least one example embodiment may be used in both a subtractive electroless plating (SEP) process where the copper plating layer is selectively removed by using a chemical plating technique and a subtractive process (SAP) where the copper plating layer is selectively removed by using electroplating and chemical etching.

While the inventive concepts have been particularly shown and described with reference to embodiments thereof, it will be understood that various changes in form and details may be made therein without departing from the spirit and scope of the following claims.

What is claimed is:

1. A method of manufacturing a semiconductor package, the method comprising:
forming a wiring structure;
applying a photoresist layer onto the wiring structure;
exposing and developing the photoresist layer to form a photoresist pattern including a plurality of openings;
forming at least one bump pad by filling at least a portion of at one of the plurality of openings with a conductive material; and
planarizing the at least one bump pad by selectively polishing the at least one bump pad through a chemical mechanical processing (CMP) process using a slurry and a polishing pad.

2. The method of claim 1, further comprising:
forming, within a remainder of the at least one of the plurality of openings, a metal pad on the planarized at least one bump pad; and
removing the photoresist pattern.

3. The method of claim 1, wherein the polishing pad has a porous structure configured to selectively polish the at least one bump pad with respect to the photoresist pattern.

4. The method of claim 3, wherein the porous structure has a porosity of 50% to 80%.

5. The method of claim 1, wherein the polishing pad comprises:
a polishing surface, and
at least one radial groove on the polishing surface.

6. The method of claim 1, wherein the slurry comprises 1 percent by weight (wt %) or less of abrasive particles.

7. The method of claim 1, wherein the slurry comprises monodisperse abrasive particles having a polydispersity index (PDI) of 0.1 or less.

8. The method of claim 1, wherein the slurry comprises abrasive particles having an average particle size of 1 nanometers (nm) to 50 nm.

9. The method of claim 1, wherein the slurry comprises 5 percent by weight (wt %) or less of an oxidizing agent, the oxidizing agent configured to generate a metal ion by oxidizing the conductive material.

10. The method of claim 1, wherein the slurry comprises 5 percent by weight (wt %) or less of an amino acid complexing agent, the amino acid complexing agent configured to form a chelated agent with an ion of the conductive material.

11. The method of claim 1, wherein, in the planarizing of the at least one bump pad, surface of the polishing pad is conditioned by a polishing pad conditioner to maintain surface roughness, and
the polishing pad conditioner has a surface roughness average configured to overcome a step difference between the photoresist pattern and the at least one bump pad and to selectively polish a surface of the at least one bump pad.

12. The method of claim 11, wherein an outer surface of the polishing pad conditioner includes a plurality of abrasive crystals, the plurality of abrasive crystals having octahedral shapes.

13. The method of claim 12, wherein the octahedral shapes of the plurality of abrasive crystals have an edge of a length of 100 micrometers (μm) to 350 μm.

14. A method of manufacturing a semiconductor package, the method comprising:
forming an insulating film;
applying a photoresist layer onto the insulating film;
exposing and developing the photoresist layer to form a photoresist pattern including a plurality of openings;
forming a metal material film in the plurality of openings;
selectively polishing and planarizing the metal material film through a chemical mechanical processing (CMP) process, the CMP process using a slurry and a polishing pad; and
removing the photoresist pattern.

15. The method of claim 14, wherein the polishing pad has a porous structure configured to selectively polish the metal material film with respect to the photoresist pattern.

16. The method of claim 14, wherein the polishing pad comprises:
a polishing surface, and
a radial groove on the polishing surface.

17. The method of claim 14, wherein the slurry comprises 1 percent by weight (wt %) or less of abrasive particles.

18. The method of claim 14, wherein the slurry comprises abrasive particles having an average particle size of 1 nanometers (nm) to 50 nm.

19. A method of manufacturing a semiconductor package, the method comprising:
forming a wiring structure;
applying a photoresist layer onto the wiring structure;
exposing and developing the photoresist layer to form a photoresist pattern including a plurality of openings;
forming at least one bump pad by filling at least a portion of at least one of the plurality of openings with a conductive material;
planarizing the at least one bump pad by selectively polishing the at least one bump pad through a chemical mechanical processing (CMP) process, the CMP process using a slurry and a polishing pad;
forming, within a remainder of the at least one of the plurality of openings, a metal pad on the planarized at least one bump pad;
removing the photoresist pattern;
arranging a semiconductor chip on the metal pad; and
forming a molding layer surrounding the semiconductor chip.

20. The method of claim 19, wherein
the polishing pad has a porous structure having a porosity of 50% to 80%,
the polishing pad has a polishing surface and a radial groove on the polishing surface, and the slurry comprises 1 percent by weight (wt %) or less of abrasive particles having an average particle size of 1 nanometers (nm) to 50 nm.
